(19) United States
(12) Patent Application Publication
(10) Pub. No.: US 2009/0162966 A1
(43) Pub. Date: Jun. 25, 2009

(54) Structure and method of formation of a solar cell

(75) Inventors: Dharmesh Jawarani, Round Rock, TX (US); Vinod Kumar Agarwal, Monte Sereno, CA (US)

Correspondence Address: FORTKORT & HOUSTON P.C., 9442 N. CAPITAL OF TEXAS HIGHWAY, ARBORETUM PLAZA ONE, SUITE 500, AUSTIN, TX, 78759, US

(73) Assignee: The Woodside Group PTE LTD

(21) Appl. No.: 12/004,534

(22) Filed: Dec. 21, 2007

(51) Int. Cl. H01L 33/00

(52) U.S. Cl. 438/67; 257/E33.055

(57) ABSTRACT

A semiconductor device is formed on a low cost substrate 312 onto which is deposited a metal film 314 that serves as an intermediate bonding layer with a transferred film 324 of semiconducting material from a bulk semiconductor substrate 322. The metal film forms an intermetallic compound such as a silicide 316 and functions as a bonding agent between the low cost substrate and the semiconducting substrate, as a back surface field for reflection of minority carriers, and as a textured optical reflector of photons. The silicide also forms a low resistivity back-side ohmic contact with the semiconductor layer. This results in a low cost, flexible, high efficiency, thin film solar cell device.

### FIELD OF THE DISCLOSURE

The present disclosure relates generally to semiconductor devices, and more specifically to methods for fabricating solar cells.

### BACKGROUND OF THE DISCLOSURE

Solar cells are devices that convert light energy into electrical energy by way of the photovoltaic effect. Solar cells operate through the photogeneration of charge carriers (electrons and holes) in absorbing material. The charge carriers so produced are then collected by conductive contacts to produce an electrical current.

FIG. 1 depicts one known type of solar cell. A description of this cell may be found, for example, at http://en.wikipedia.org/wiki/Solar cell). The solar cell 101 depicted therein is silicon based, and comprises a wafer 103 of p-type silicon. The wafer 103 is capped on one end with a layer of oxide 105, a region of p+ type silicon 115 and an aluminum back contact 107, and is capped on the other end with a layer of n-type silicon 109, a layer of SiO₂ 111 and an anti reflective coating (ARC) 113. A series of surface contacts 121 are provided which are in electrical contact with the layer of n-type silicon 109. The surface contacts 121 are, in turn, in electrical contact with the back contact 107 by way of a circuit 117 equipped with a resistor 119. The surface contacts in the particular embodiment depicted comprise layers of Ag 121, Pd 123, and Ti 125.

In operation, photons 127 impinge upon the solar cell 101. Some of these photons are scattered by the ARC 113. Other photons of a suitable energy are absorbed by the p-type silicon 103, where they dislodge electrons from the atoms in the semiconductor lattice. The dislodged electrons flow through the p-type silicon 103 and into the N-type silicon 109, where they are gathered by the surface contacts 121 and produce an electrical current in circuit 117. Corresponding holes are also generated which are collected in P+ wells 115 created in the p-type silicon 103.

FIG. 2 depicts another type of silicon-based solar cell currently known to the art. The solar cell 151 depicted therein comprises a p-type silicon base 153 having a thickness w which is equipped with a rear contact 155. The p-type silicon base 153 is further equipped with a doped emitter region 157 having a thickness t. The doped emitter region 157 is capped with a textured surface 159, though in some cases the textured surface 159 may be replaced by, or used in conjunction with, an ARC. A bus bar 161 is disposed upon the textured surface, and is equipped with a plurality of fingers 163 which are adapted to collect electrons generated by the photovoltaic effect in the p-type silicon base 153.

Silicon-based solar cells constitute a large portion of the global photovoltaic market, and may be made by known semiconductor fabrication techniques. In recent years, the high demand for silicon-based solar cells has created a shortage in the raw polysilicon feedstock used to manufacture these cells. This shortage has resulted in significant price increases in the final solar cell modules. Consequently, considerable effort has been expended in the art towards developing less expensive photovoltaic modules.

One approach to reducing the price of photovoltaic modules is to reduce the amount of silicon used in these modules. This approach is currently being pursued by several photovoltaic manufacturers who use alternative thin film technologies, such as those based on amorphous silicon, copper indium gallium selenide (CIGS), and cadmium telluride (CdTe). However, these approaches frequently yield lower efficiency solar cells, or suffer from volume manufacturing issues.

Another general approach of forming silicon-based thin film solar cells is through the use of layer transfer methods such as those typified by the SMART CUT® or ELTRAN® (Epitaxial Layer Transfer) processes. An example of the SMART CUT® process is illustrated in FIGS. 3-7.

With reference to FIG. 3, a first wafer 201 is provided which comprises a silicon substrate 203 capped with a dielectric layer 205. The dielectric layer 205 may comprise, for example, SiO₂. A second wafer 207 is also provided.

As shown in FIG. 4, the first wafer 201 is then subjected to hydrogen implantation at a dose within the range of 3.5×10¹⁶ to 1×10¹⁷ cm⁻², which produces a microcavity zone 208 in the silicon substrate 203. The first 201 and second 207 wafers are then cleaned using a modified RCA (Radio Corporation of America) process.

Referring now to FIG. 5, the first 201 and second 207 wafers are then hydrophilically bonded to each other at room temperature. The resulting structure is then subjected to a two-phase heat treatment. During the first phase, which is conducted at 400-600° C., the implanted first wafer 201 splits into two parts along the microcavity zone 208 as shown in FIG. 6 such that a thin layer of monocrystalline silicon 213 from the silicon substrate 203 remains bonded to the second wafer 207, thereby giving rise to an SOI structure 215. The second phase of the heat treatment, which is conducted at around 1100° C., strengthens the chemical bonds between the thin layer of monocrystalline silicon 213 and the dielectric layer 205.

After splitting, the SOI structure 215 exhibits micro-roughness along the surface of the thin layer of monocrystalline silicon 213. Wafer 203 has a similarly roughened surface 211. These surfaces are thus subjected to polishing as shown in FIG. 7 to reduce their surface roughness. Silicon substrate 203, whose surface layers 213 and 205 have been removed by the splitting process (see FIGS. 5-6), can then be recycled for use as the first 201 or second 207 wafer in subsequent process flows.

In the ELTRAN® process, a porous layer of silicon is created on a second substrate using HF-based etchants, and then an epitaxial Si film is grown on this porous layer. Wafer bonding is used to attach the top of the porous film to a first substrate. Splitting of the second substrate from the epitaxial film along the porous layer is accomplished via the use of a water jet.

While the foregoing processes have been moderately successful in creating lab-scale solar cells, none has reached commercial production levels. In the case of the ELTRAN® process, this failure is believed to arise, at least in part, from the presence of defects in the epitaxial layers. In the case of the SMART CUT® method, this failure is believed to be attributable to materials and temperature incompatibility issues that either lead to delamination of the transferred layers from the SOI structure 215 (see FIGS. 6-7), or incomplete transfer of the thin films 213 and 205 from the first wafer 201.

While a thin film solar cell of the type achievable with the foregoing processes will theoretically have a higher conversion efficiency (for conversion of solar energy to electrical energy) compared to thick film or bulk devices as a result of reduced minority carrier recombination, the use of thin films also typically results in less absorption of optical photons. In general, the thickness of the device should exceed the absorption length for efficient light absorption. Therefore, it is frequently desirable to increase the optical path of photons in the thin film device through a suitable optical confinement technique.

One optical confinement technique known to the art involves texturing of the emitter regions and the application of an anti reflection coating (ARC) layer on top of those portions of the emitter regions which are not covered by contacts. These approaches are exemplified, for example, by the structures depicted in FIGS. 1-2. However, front side texturing increases the dark current and, therefore, reduces the open circuit voltage (V_{OC}) and the fill factor of a solar cell.

Backside texturing, though less commonly used, is theoretically more effective in increasing the optical path of the photons. However, conventional backside texturing has its own challenges, since the front side has to be masked while the backside is etched for texturing. The backside must then be thoroughly cleaned so that the deposited metal forms a good ohmic contact after alloying or sintering. This process is complicated by the fact that the alloying or sintering steps create a deep graded layer at the metal-semiconductor interface that actually absorbs photons rather than reflecting them back into the semiconductor where they can be used for generating electron-hole pairs. There is thus a need in the art for a method for creating backside texturing to increase the optical absorption of any low energy photons that did not get used up to generate charge carriers before reaching the back surface.

One common rule of thumb utilized in designing solar cells is that the minority carrier diffusion length should be at least twice the thickness of the solar cell. In a monocrystalline or a large grain multicrystalline Si wafer, the diffusion length is around 100 μm or more. However, as the device gets thinner, surface (and not bulk) recombination becomes more important in such wafers. For electrons in p type silicon, the surface recombination velocity Sₙ at untreated surfaces, and at interfaces with metallic contacts, is in the range of 1,000-100,000 cm/s. When the surface is passivated with a layer of silicon dioxide, the oxide shields the minority carriers from defects at the surface and reduces Sₙ to less than 100 cm/s. In a conventional solar cell, the rear surface is doped more heavily to create a back surface field, which helps to reduce the loss of carriers through surface recombination. The extra p⁺-p junction also adds to the built-in bias of the cell and may enhance V_{OC}.

In general, a silicon-metal interface is more defective than a silicon-silicon dioxide interface. Therefore, it is advantageous to form rear contacts as well as point contacts while the non-contacting regions are passivated with silicon dioxide similar to the front side. However, in order to do this, one has to create gaps in the oxide film to dope the base region heavily and to diffuse the metal locally in order to form the rear contact. There is thus a need in the art for a method for creating a defect free rear interface that reduces surface recombination at the metal-semiconductor interface without the need for additional complexity such as lithography and etch of the passivating oxide and localized diffusion of rear contacts.

The foregoing needs in the art may be met by the devices and methodologies disclosed herein and hereinafter described.

### BRIEF DESCRIPTION OF THE DRAWINGS

FIG. 1 is a prior art Si-based solar cell structure.

FIG. 2 is a prior art solar cell structure.

FIGS. 3-7 are illustrations depicting steps in a prior art process for making Si-based thin film solar cells.

FIGS. 8-15 are illustrations depicting steps in a first particular, non-limiting embodiment of a process in accordance with the teachings herein.

FIG. 16 is an illustration depicting the recyclability of a wafer in the process of FIGS. 8-15.

FIGS. 17-22 are illustrations depicting steps in a second particular, non-limiting embodiment of a process in accordance with the teachings herein.

FIGS. 23-26 are illustrations depicting steps in a third particular, non-limiting embodiment of a process in accordance with the teachings herein.

FIGS. 27-31 are illustrations depicting steps in a fourth particular, non-limiting embodiment of a process in accordance with the teachings herein.

FIGS. 32-34 are illustrations depicting steps in a fifth particular, non-limiting embodiment of a process in accordance with the teachings herein.

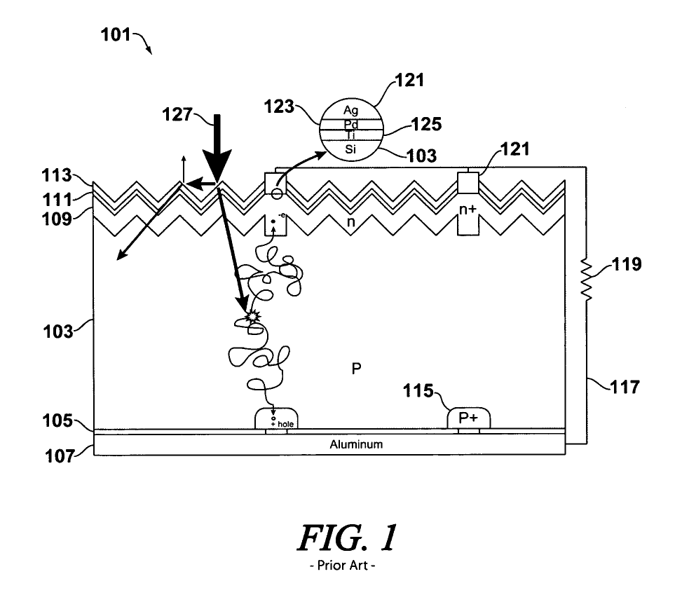

### SUMMARY OF THE DISCLOSURE

In one aspect, a method for forming a photovoltaic device is provided which comprises (a) providing a first substrate having a metal layer disposed thereon; (b) providing a second substrate which comprises a semiconductor material; (c) bringing the metal layer and the second substrate into contact with each other; and (d) interdiffusing the metal layer and the semiconductor material.

In another aspect, a method for forming a photovoltaic device is provided which comprises (a) providing a first substrate having a metal layer disposed thereon; (b) providing a plurality of structures, wherein each of said structures comprises a semiconductor layer; (c) bringing the metal layer and the plurality of semiconductor structures into contact with each other; and (d) interdiffusing the metal layer and the semiconductor layers of the plurality of structures.

In a further aspect, a photovoltaic device is provided which comprises (a) a substrate; (b) a semiconductor layer; and (c) a metal silicide layer disposed between said substrate and said semiconductor layer.

### DETAILED DESCRIPTION

It has now been found that the aforementioned needs in the art may be met through the use of metal silicides or other metal-semiconductor intermetallic compounds to fabricate solar cells. Such materials may be utilized to simultaneously create a bonding agent, a back surface field (BSF), an optical reflecting layer, and/or a low resistivity rear ohmic contact in solar cell structures. The methodologies described herein may be utilized to fabricate low cost thin film solar cells having high efficiency, and may also be employed to create structures having multiple solar cells disposed on a common substrate, wherein the cells themselves may be fabricated using other techniques and structures as are known to the art.

By way of example, devices may be made in accordance with the teachings herein by a process which includes (a) splitting a semiconducting thin film from a semiconductor substrate; (b) depositing a metal film on a handle substrate such as stainless steel, metal foil, plastic or glass; and (c) bonding the metalized handle substrate to the semiconductor substrate with the use of an annealing treatment to form an intermetallic compound such as a metal silicide layer. The metal silicide and the processing conditions utilized may be chosen such that a textured layer is formed between the semiconducting layer and the metalized substrate. Such a textured layer increases the optical absorption path for photons. The silicide film may also be chosen such that a back surface field is created due to preferential accumulation of the dopants at the silicide-silicon interface, and so that it also forms a low resistivity rear ohmic contact to the base region. Finally, thermal sequences may be utilized which do not adversely affect conventional downstream silicon solar cell processing.

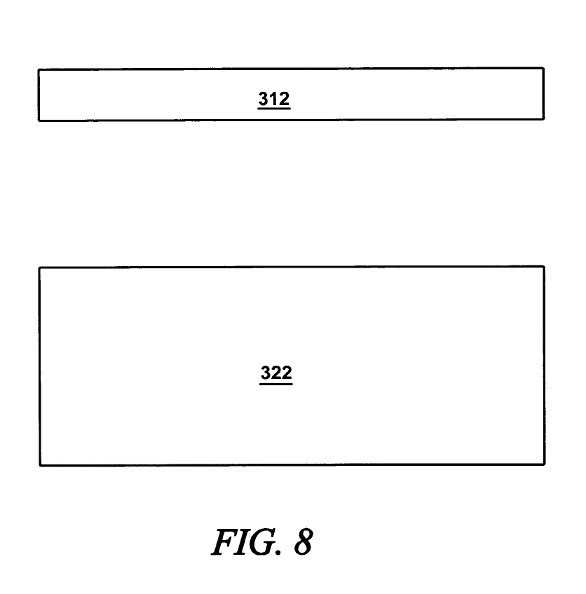

FIGS. 8-13 depict a first particular, non-limiting embodiment of a process for making a solar cell in accordance with the teachings herein. With reference to FIG. 8, a first substrate 312 and a second substrate 322 are provided. The first substrate 312 is preferably a low cost substrate which may comprise, for example, stainless steel, Ti, Ta, Mo, various types of plastics (including, for example, polyimides), and various types of doped glasses. The first substrate 312 preferably has a thickness within the range of about 50 μm to about 150 μm in the case of metal foils, and preferably has a thickness of about 2.5 mm to about 3.5 mm, and more preferably a thickness of about 3 mm, in the case of glass. Preferably, the first substrate 312 is also capable of withstanding temperatures in excess of about 400° C., since this facilitates subsequent processing steps.

The second substrate 322 is preferably a semiconductor substrate, and is more preferably a silicon substrate. N-type monocrystalline silicon substrates may be utilized as the second substrate 322, although multicrystalline and p-type wafers may also be utilized. In some embodiments, other types of substrates, such as, for example, substrates comprising Ge or GaAs, may also be utilized. The second substrate 322 has a thickness which is preferably within the range of about 500 μm to about 700 μm, and more preferably within the range of about 550 μm to about 650 μm. Most preferably, the second substrate 322 has a thickness of about 600 μm in the case of N-type substrates.

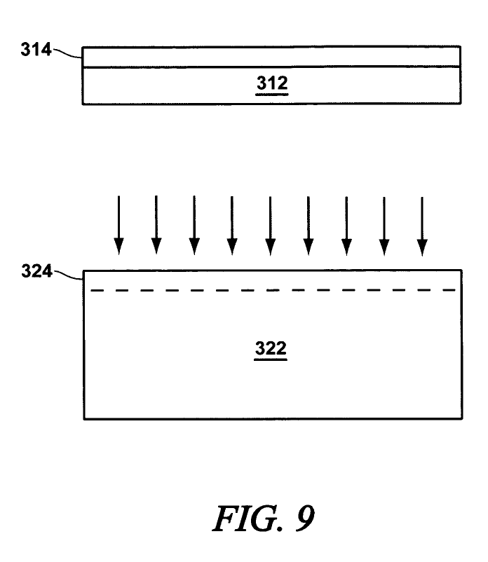

Referring now to FIG. 9, a metal film 314 is deposited on the first substrate 312. The metal film 314 may comprise various metals including, without limitation, Co, Ni, Ti, Pt, Mo, Zr, Cr, Pd, Al, Ag, Au, Ir, Er, Yb, Cu, Ta, Hf and W, and may be formed using various processes including, but not limited to, sputtering, evaporation, electroplating, and electroless deposition. As explained in further detail below and as seen in FIG. 15, the metal film 314 forms what will ultimately become the rear contact of a solar cell. In some cases, a dielectric film, such as SiO₂ or Al₂O₃, may be deposited on the first substrate 312 prior to deposition of the metal film 314. This is especially desirable in the case of monolithic integration of several solar cells on a common substrate as described later.

Still referring to FIG. 9, a p-type layer 324 is then formed in the second substrate 322. Preferably, the p-type layer 324 is formed by implanting a first dopant (which is preferably a trivalent, ionic species such as boron) into the top surface of the second substrate 322, and then activating the first dopant through a suitable rapid thermal anneal process. The rapid thermal anneal process may involve, for example, exposing the second substrate 322 to 1000° C. in an N₂ atmosphere. Alternatively, the p-type layer 324 may instead be formed using gaseous or solid state diffusion methods as are known in the art.

Various doping levels may be employed in forming the p-type layer 324 with the first dopant, although a concentration within the range of about 1×10¹⁶ to about 1×10²⁰ ions/cm³ is preferred. The average energy of the B³⁺ ions used in the implantation process is preferably chosen such that the p-type layer 324 has a depth within the range of about 0.01 μm to about 10 μm, and more preferably within the range of about 0.1 μm to about 1 μm. Most preferably, the p-type layer 324 has a depth of about 0.2 μm.

In some embodiments, it may be advantageous to utilize a second implantation step to implant a second dopant (at a higher dose than the first dopant) in the top surface of the second substrate 322 such that, in the resulting structure, a p+ type layer (not shown) is formed on top of the (lower doped) p-type layer 324. Such an approach may be utilized to form a p+-p junction for a rear BSF, and may facilitate at a subsequent stage the formation of the NiSi₂ silicide phase (if Ni is used) at the metal-silicon interface. The second dopant may be any suitable dopant, and may be the same as, or different from, the first dopant. Preferably, however, in such embodiments, the first and second dopant are the same.

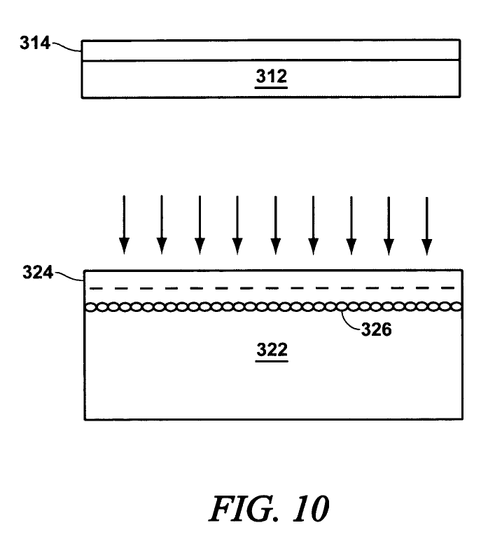

Referring now to FIG. 10, a defect surface 326 is formed in the second substrate 322 through ion implantation and heating. The ion implantation is achieved with suitable ions, such as H, He, or Ar ions, which are implanted to a predetermined depth within the second substrate 322. In some embodiments, an oxide layer (not shown) may be deposited on top of the second substrate 322 prior to the ion implantation step. Such an oxide layer may prevent channeling of the H, He or Ar ions, and may prevent damage to the top surface of the second substrate 322. If an oxide layer is utilized, it may be removed with a dilute HF-based solution after implantation.

Subsequent to the ion implantation, the second substrate 322 may be subjected to a suitable anneal to join the microcavities formed by the ion implantation step and thereby complete the defect surface 326. This anneal may be conducted, for example, at a temperature of about 500° C. for a duration of about 30 minutes. Of course, it will be appreciated that, at this stage of the process, the portion of the second substrate above the defect surface 326 remains attached to the remainder of the second substrate 322.

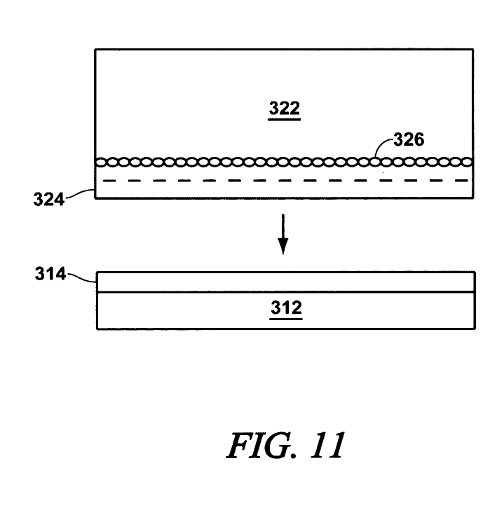

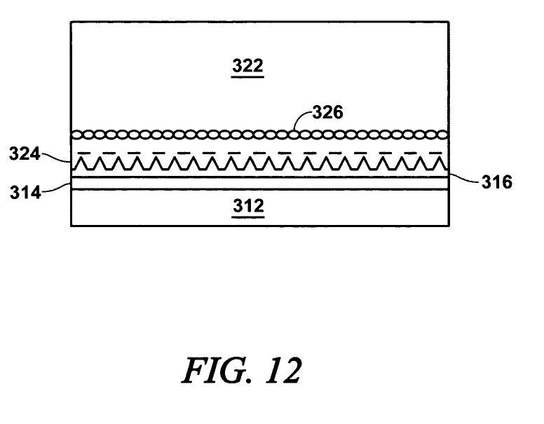

Referring now to FIG. 11, the second substrate 322 is placed upside down on the metal film 314 of the first substrate 312, and the resulting structure is subjected to a suitable heat treatment. The parameters of the heat treatment are selected to cause the metal film 314 and the adjacent surface of the second substrate 322 to react and form a silicide layer 316 at the interface as shown in FIG. 12. It should be noted that both the second substrate 322 and the metal film 314 should have very smooth surfaces such that a uniformly bonded stack is obtained following this step. The annealing step is preferably performed in an inert atmosphere.

When the second substrate 322 comprises silicon, a preferred metal of choice for the metal film 314 is Ni, since Ni readily forms nickel silicide under rapid thermal annealing at temperatures within the range of about 350° C. to about 1200° C., and preferably within a range of from about 400° C. to about 700° C. The preferred phase is NiSi₂, which is stable at temperatures up to about 800° C. Advantageously, in the presence of either tensile lattice strain or a heavy doping of boron atoms (p+) in the first substrate 322, the silicon lattice of the second substrate 322 shrinks by an appropriate amount such that the formation of the NiSi₂ phase is favored over the usual NiSi phase.

The morphology of the face centered cubic (FCC) NiSi₂ phase is such that it forms with facets along {111} planes of the diamond cubic silicon lattice due to near perfect lattice matching between NiSi₂ and Si under these conditions. This leads to a lowering of the interfacial energy of formation of the new phase so that the resultant phase formation with {111} facets forms a textured layer which is excellent for causing multiple reflections of incident photons in the thin film solar cell. Hence, this phase formation increases the optical path of the photons for increased absorption within the thin film solar cell thus formed.

The use of a p-type layer 324 facilitates the formation of the NiSi₂ phase. It should be noted, however, that if the temperature requirements for downstream processing exceed about 850° C., then other metals may be used whose silicides can withstand higher temperatures. Examples of such metals include, but are not limited to, Ti, Co, W and Mo. The respective silicides of these metals (TiSi₂, CoSi₂, WSi, and MoSi) are stable up to 1000° C. or more for several seconds. Furthermore, dopant segregation occurs readily at the silicide-silicon interface during silicidation, thereby leading to lower barrier heights and contact resistivities. This phenomenon may be utilized to lower the series resistance of the solar cell device and, therefore, to increase its efficiency.

In some embodiments, formation of a uniform silicide may significantly reduce defects at the metal-silicide boundary, since dangling bonds are passivated at the metal-silicon interface by the formation of intermetallic silicide compounds. This effect is similar to that observed with oxide films which passivate the front or rear surface of otherwise free silicon, thereby reducing the effective surface recombination velocity and increasing the chances that photo-generated carriers are collected for producing electrical current. This is especially true in the case of NiSi₂ formation, since NiSi₂ forms with near perfect lattice matching to the contacting silicon substrate and, therefore, may give rise to fewer defects or dangling bonds at the interface. Metal silicides are generally also good conductors of electricity, and form good ohmic contacts to silicon.

The metal silicide formed during the rapid thermal anneal serves multiple purposes. These include the formation of an ohmic contact, the formation of an optical backside reflector, the formation of a backside surface field that repels minority carriers, and the formation of an intimate bond between the first 312 and second 322 substrates.

It should also be noted that, in some embodiments of the methodology described herein, after the second substrate 322 has been implanted with H, He, or Ar ions for splitting, a second metal film may be deposited on the top surface of this wafer in addition to the metal film 314 formed on the first substrate 312. These two substrates may then be bonded via diffusion bonding to create an intimate bond. In this case, the diffusion bonding conditions (e.g., temperature, pressure, and atmosphere) that are selected may be different from the downstream annealing/RTA conditions that form the silicide upon further annealing. However, through appropriate selection of the diffusion bonding conditions, a silicide film having the desired properties mentioned above can still be obtained.

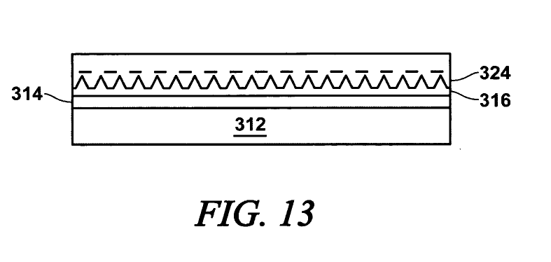

As shown in FIG. 13, further processing of the stack accomplishes splitting of the second substrate 322 from the first substrate 312 with the use of a tensile or shear stress or a combination of both. It is also possible to use a rapid thermal anneal (RTA) process or other suitable annealing treatments to accomplish this end. Such annealing treatments may utilize temperatures within the range of about 400° C. to about 1100° C.

In some embodiments, the anneal used to complete the definition of the defect surface 326 may be used to split the wafer, in which case the first 312 and second 322 substrates may be brought together as shown in FIG. 11 prior to the anneal. The substrate types and the metal (silicide) types utilized may dictate the maximum annealing temperature that may be utilized for splitting the second substrate 322 across the defect surface 326, since the difference in coefficient of thermal expansion between the first 312 and second 322 substrates may cause cracking of either substrate if care is not taken.

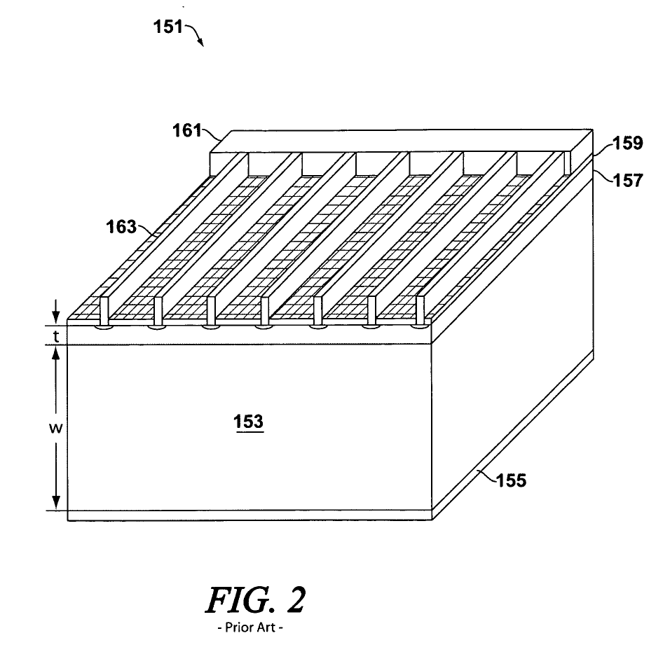

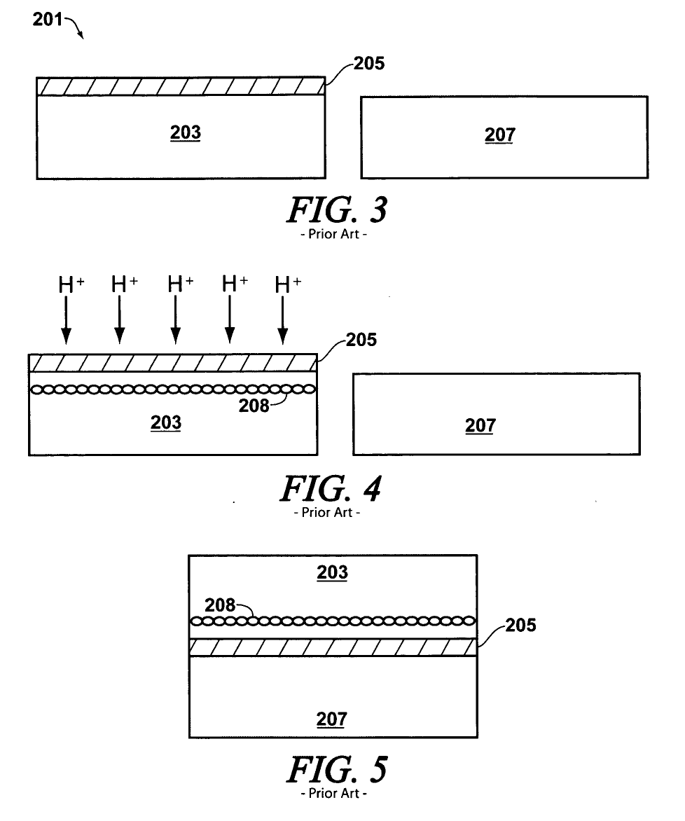

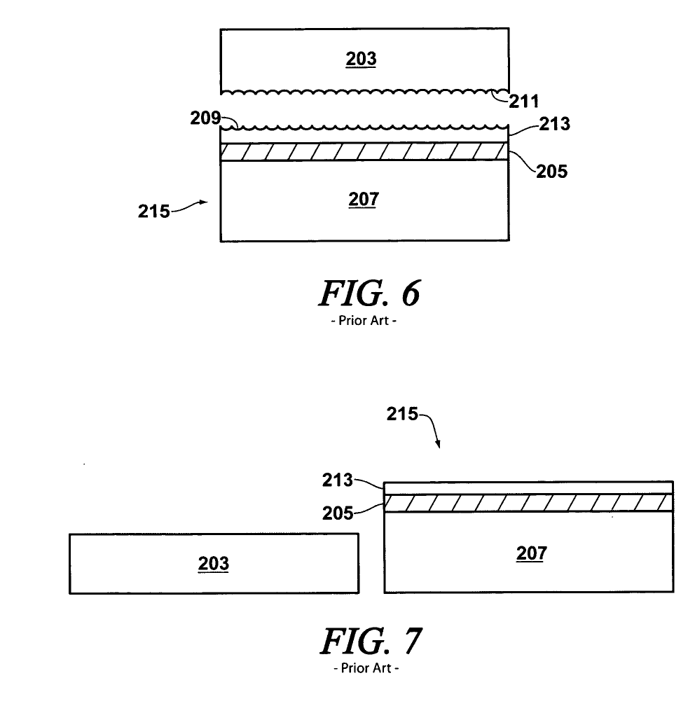

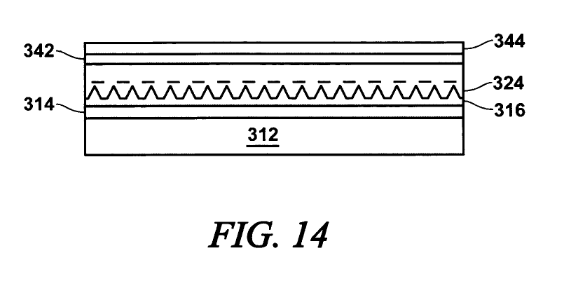

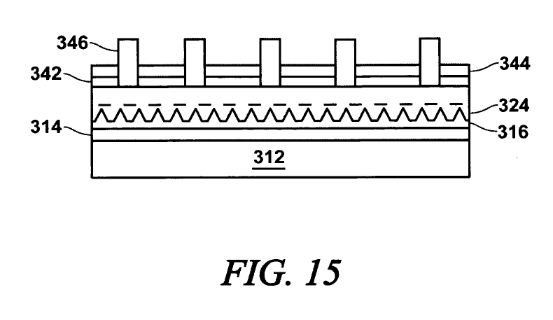

FIG. 14 illustrates further processing steps which may be utilized to complete the formation of the solar cell. These steps include depositing a thin (preferably oxide) passivating film 342 on the front surface of the cell, followed by depositing an anti-reflection coating (ARC) (preferably comprising SiN) 344 on the front surface to increase absorption of incident radiation. This is followed by contact printing and firing on the front and optionally on the rear side to form the metal contact fingers and busbars 346 as shown in FIG. 15. The resulting structure may generally resemble the device of FIG. 2 in a three dimensional aspect. The second substrate 322 is then subjected to touch up chemical mechanical polishing (CMP) to smooth the surface to an RMS roughness of about 5 Å or less, and is cleaned with a suitable cleaning chemistry for reuse multiple times.

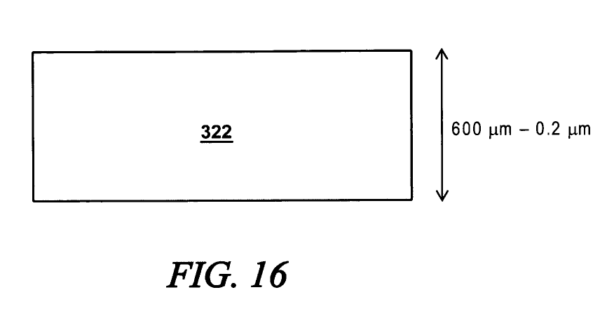

As seen in FIG. 16, a typical use of the second substrate 322 reduces its thickness by about 0.2 μm, and the substrate 322 may typically be reused until it is about 200 μm thick. Hence, if the second substrate 322 is 600 μm thick, it may be potentially reused about 2000 times, after which it may be used for conventional Si solar cell processing. If needed, touch up polishing and cleaning may also be used for the first substrate 312 after splitting to smooth out any roughness and non-uniformity of the top surface prior to depositing the oxide passivating film on this substrate. However, it may be advantageous in some instances to let this roughness remain on the top surface so as to create a natural front-side texture for the solar cell thus formed.

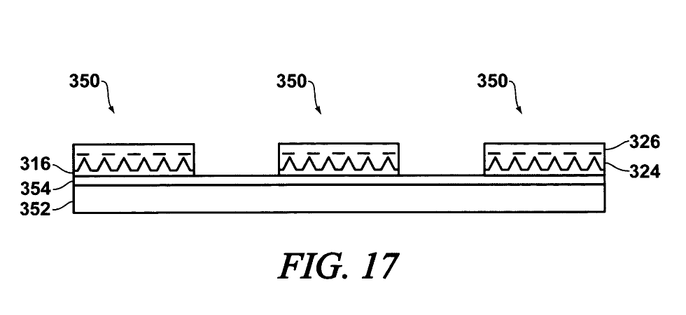

FIGS. 17-22 illustrate a further embodiment of a process in accordance with the teachings herein. This process involves the monolithic integration of a solar module consisting of multiple cells arranged in series and in parallel, and utilizes plasma etching, mechanical scribing or laser grooving to connect the solar cells and the top and bottom electrodes. This approach is especially useful in applications in which the starting substrate is a rigid or insulating material (such as, for example, doped glass), and in which thin film layers are to be transferred onto the substrate during later processing steps.

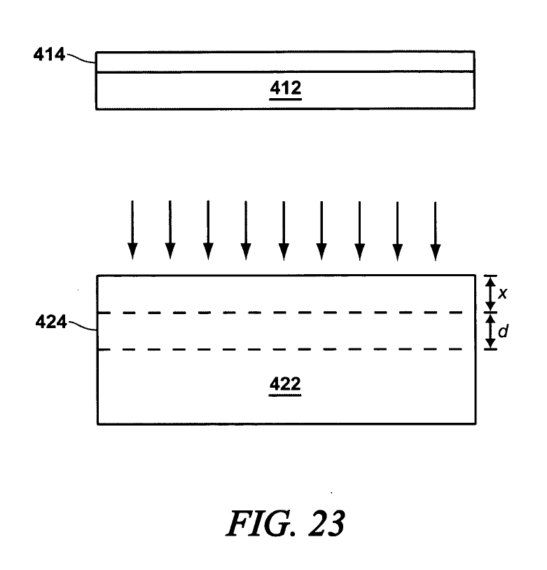

With reference to FIG. 17, multiple cells 350, which may be fabricated with the methodology depicted in FIGS. 8-13 (or in accordance with the methodologies depicted in FIGS. 23-34), may be placed onto a glass substrate 352 with a metal layer 354 disposed thereon. In the structure depicted, silicidation and splitting have already been carried out after placing a plurality of wafers face down in contact with metal layer 354 and using an appropriate heat treatment to first form the silicide and then to split off the wafers.

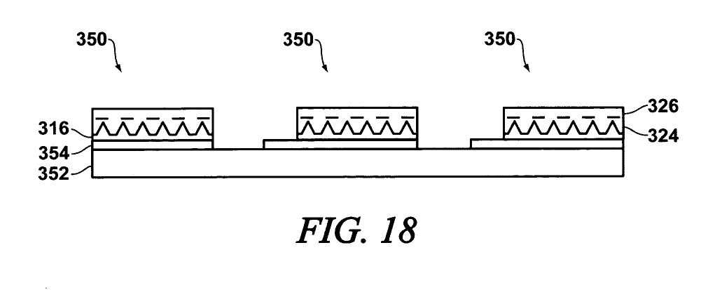

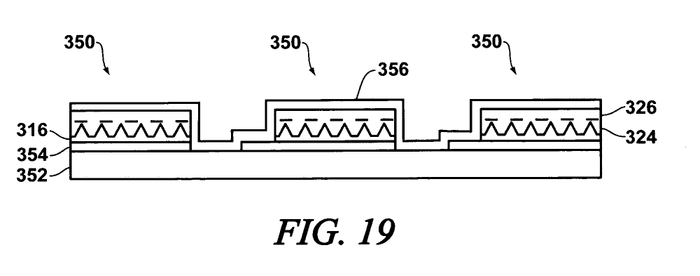

As shown in FIG. 18, the metal film 354 is then scribed, grooved or etched to form individual back contacts for the transferred layer cells 350. Next, an insulating film 356 such as SiO₂ or SiN is deposited on the substrate 352 as shown in FIG. 19.

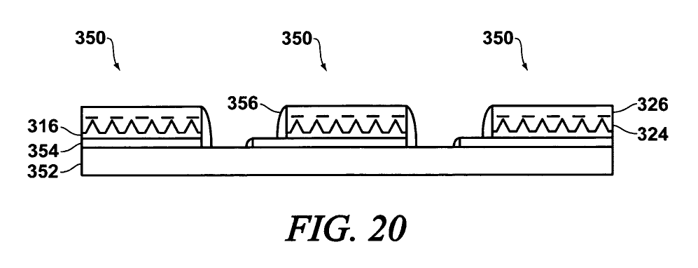

A blanket etch of the insulating film 356 is then utilized to remove the insulating film 356 from the top of the metal layer 354 and the semiconductor surfaces while providing isolation to the sides of the cells as shown in FIG. 20. This step is similar to the square spacer etch which is used in the semiconductor industry to form insulating spacers around the gate regions of a CMOS transistor.

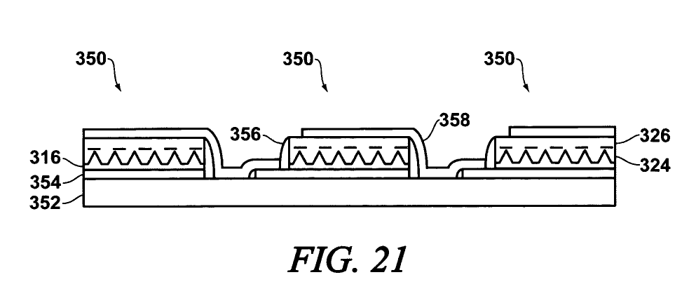

As shown in FIG. 21, metal contacts 358 are then deposited over the structure to join the individual cells 350 in series. This may be accomplished through screen printing or by evaporating a metal such as aluminum through a shadow mask. Alternatively, a transparent conducting oxide (TCO) may be sputter deposited on the structure and then patterned using a laser groove to isolate the cells 350 and to complete the monolithic integration of the series of cells 350 into a solar module. In this case, a metal or an alloy (such as, for example, Ti—Pd—Ag) may be deposited to form the front contact grid lines and bus bars.

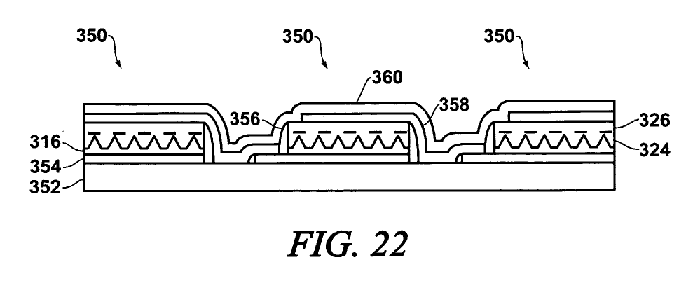

A final step of depositing an SiO₂ film followed by an ARC film (which preferably comprises SiN) (shown collectively as element 360) completes the integration of the solar cell module as shown in FIG. 22. The deposition of a SiN ARC film is useful in embodiments in which a TCO is not employed and in which the semiconductor surface (where not covered by metal grid lines and bus bars) is exposed.

FIGS. 23-26 depict another particular, non-limiting embodiment of a process for making a solar cell in accordance with the teachings herein. With reference to FIG. 23, a first substrate 412 and a second substrate 422 are provided. The first substrate 412 may be any of the types described above, and preferably has a thickness within the range of about 50 μm to about 150 μm in the case of metal foils, or has a thickness of about 2.5 mm to about 3.5 mm, and more preferably a thickness of about 3 mm, in the case of glass.

The second substrate 422 is preferably a semiconductor substrate, and is more preferably a silicon substrate. The use of p-type monocrystalline silicon substrates as the second substrate 422 in this particular embodiment is preferred. The second substrate 422 preferably has a dopant concentration within the range of about 1×10¹⁶ to about 1×10²⁰ cm⁻³. In some embodiments, substrates containing materials other than silicon, such as, for example, substrates comprising Ge or GaAs, may also be utilized. The second substrate 422 has a thickness which is preferably within the range of about 500 μm to about 700 μm, and more preferably within the range of about 550 μm to about 650 μm. Most preferably, the second substrate 422 has a thickness of about 600 μm.

Still referring to FIG. 23, a metal film 414 is deposited on the first substrate 412. The metal film 414 may comprise any of the various metals as described in the previous embodiments, and may be formed by any of the methods described with respect to those embodiments.

A buried n-type layer 424 is then formed in the second substrate 422. Preferably, the n-type layer 424 is formed by implanting a first dopant (which is preferably an ionic species such as phosphorus) into the top surface of the second substrate 422. The thickness d of this buried n-type layer 424 is typically within the range of about 0.05 microns to about 5 microns, and more preferably is within the range of about 0.1 microns to about 1 micron. The depth x of the n-type layer 424 below the top surface is typically within the range of about 0.1 microns to about 50 microns, and is preferably within the range of about 0.2 microns to about 5 microns. Multiple implants may be required in some implementations in order to achieve uniformly distributed dopant concentrations within this thickness.

If necessary, the dopant may then be activated after implantation through a suitable rapid thermal anneal process. The rapid thermal anneal process may involve, for example, exposing the second substrate 422 to 1000° C. in an N₂ atmosphere. A diffusion anneal may be employed to achieve a uniform distribution of dopant within the n-type layer, as well as to activate the dopant.

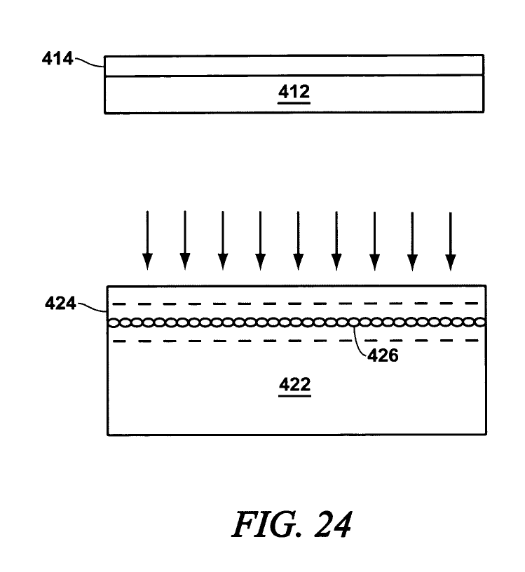

Referring now to FIG. 24, a defect surface 426 is formed in the second substrate 422 through ion implantation and heating. The ion implantation is achieved with suitable ions, such as H, He, or Ar ions, which are implanted to a predetermined depth within the second substrate 422. Preferably, the implant peak lies within the thickness d of the n-type layer formed in the previous step. In some embodiments, an oxide layer (not shown) may be deposited on top of the second substrate 422 prior to the ion implantation step. Such an oxide layer may prevent channeling of the H, He or Ar ions, and may prevent damage to the top surface of the second substrate 422. If an oxide layer is utilized, it may be removed with a dilute HF-based solution after implantation.

Subsequent to the ion implantation, the second substrate 422 may be subjected to a suitable anneal to join the microcavities formed by the ion implantation step and thereby complete the defect surface 426. This anneal may be conducted, for example, at a temperature of about 500° C. for a duration of about 30 minutes. Of course, it will be appreciated that, at this stage of the process, the portion of the second substrate above the defect surface 426 remains attached to the remainder of the second substrate 422.

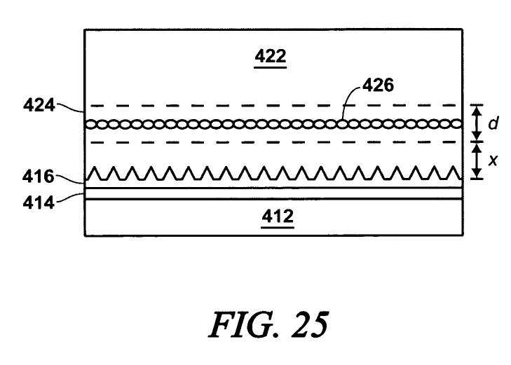

Referring now to FIG. 25, the second substrate 422 is placed upside down on the metal film 414 of the first substrate 412, and the resulting structure is subjected to a suitable heat treatment as described in the previous embodiments to cause the metal film 414 and the adjacent surface of the second substrate 422 to react and form a silicide layer 416 at the interface between the silicide layer 416 and the metal film 414.

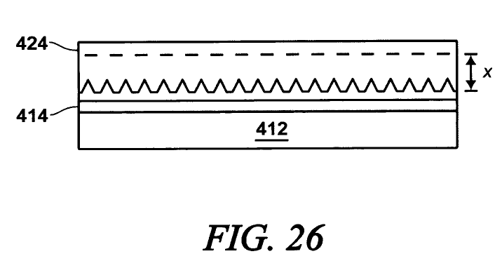

As shown in FIG. 26, further processing of the stack accomplishes splitting of the second substrate 422 from the first substrate 412 with the use of a tensile or shear stress or a combination of both, or through the use of a rapid thermal anneal (RTA) process or other suitable annealing treatments as described in the previous embodiments. Further processing steps may then be utilized to complete the formation of the solar cell as previously described.

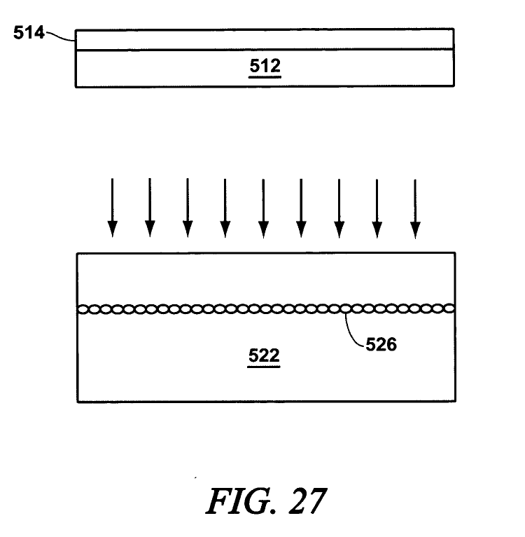

FIGS. 27-31 depict another particular, non-limiting embodiment of a process for making a solar cell in accordance with the teachings herein. With reference to FIG. 27, a first substrate 512 and a second substrate 522 are provided. The first substrate 512 may be any of the types described above, and preferably has a thickness within the range of about 50 μm to about 150 μm in the case of metal foils, or has a thickness of about 2.5 mm to about 3.5 mm, and more preferably a thickness of about 3 mm, in the case of glass.

The second substrate 522 is preferably a semiconductor substrate, and is more preferably a silicon substrate. The use of p-type monocrystalline silicon substrates as the second substrate 522 in this particular embodiment is preferred. The second substrate 522 preferably has a dopant concentration within the range of about 1×10¹⁶ to about 1×10²⁰ cm⁻³. In some embodiments, the top surface of this substrate 522 may be doped with higher concentration than the bulk to provide a p+ doped layer. This may be accomplished through ion implantation or through gaseous or solid state diffusion methods. In some embodiments, substrates containing materials other than silicon, such as, for example, substrates comprising Ge or GaAs, may also be utilized. The second substrate 522 has a thickness which is preferably within the range of about 500 μm to about 700 μm, and more preferably within the range of about 550 μm to about 650 μm. Most preferably, the second substrate 522 has a thickness of about 600 μm.

A metal film 514 is then deposited on the first substrate 512. The metal film 514 may comprise any of the various metals as described in the previous embodiments, and may be formed by any of the methods described with respect to those embodiments.

Still referring now to FIG. 27, a defect surface 526 is formed in the second substrate 522 through ion implantation and heating. The ion implantation is achieved with suitable ions, such as H, He, or Ar ions, which are implanted to a predetermined depth within the second substrate 522. In some embodiments, an oxide layer (not shown) may be deposited on top of the second substrate 522 prior to the ion implantation step. Such an oxide layer may prevent channeling of the H, He or Ar ions, and may prevent damage to the top surface of the second substrate 522. If an oxide layer is utilized, it may be removed with a dilute HF-based solution after implantation.

Subsequent to the ion implantation, the second substrate 522 may be subjected to a suitable anneal to join the microcavities formed by the ion implantation step and thereby complete the defect surface 526. This anneal may be conducted, for example, at a temperature of about 500° C. for a duration of about 30 minutes. Of course, it will be appreciated that, at this stage of the process, the portion of the second substrate above the defect surface 526 remains attached to the remainder of the second substrate 522.

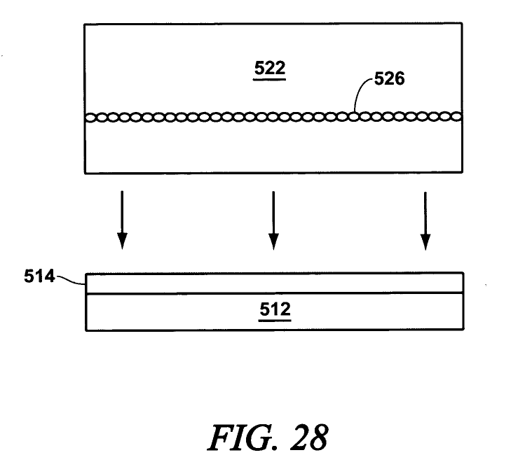

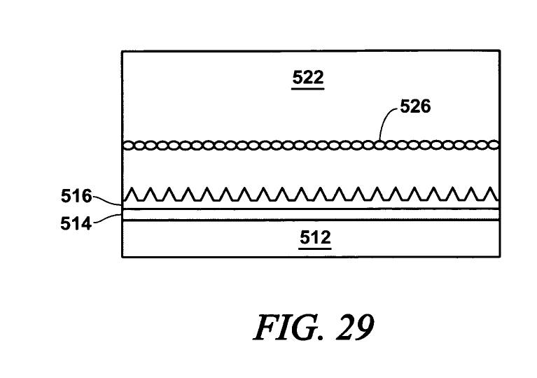

Referring now to FIG. 28, the second substrate 522 is placed upside down on the metal film 514 of the first substrate 512, and the resulting structure is subjected to a suitable heat treatment as described in the previous embodiments to cause the metal film 514 and the adjacent surface of the second substrate 522 to react and form a silicide layer 516 at the interface between them as shown in FIG. 29. The silicide layer 516 as formed may or may not be textured, depending on the type of metal used. However, other suitable texturing methods may be used as described herein. Such methods include, for example, roughening, etching, or patterning the substrate 512 prior to deposition of the metal layer 514.

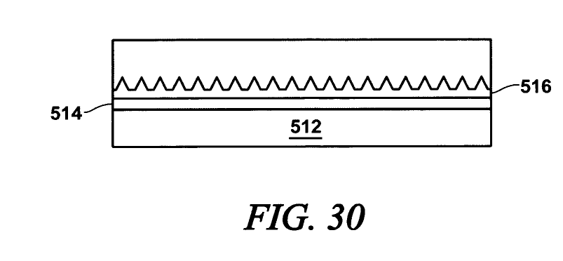

As shown in FIG. 30, further processing of the stack accomplishes splitting of the second substrate 522 from the first substrate 512 with the use of a tensile or shear stress or a combination of both, or through the use of a rapid thermal anneal (RTA) process or other suitable annealing treatments as described in the previous embodiments.

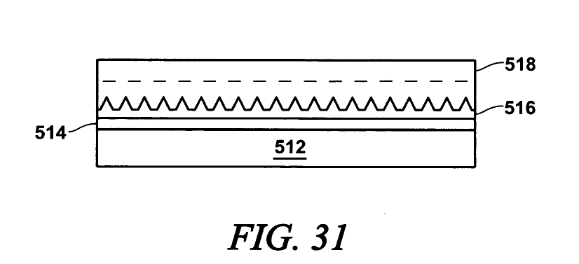

As shown in FIG. 31, an n-type layer 518 is then formed through implantation or diffusion of suitable n-type dopants at the top surface of the structure. An optional rapid thermal anneal may then be utilized to activate the dopants. Further processing steps may then be utilized to complete the formation of the solar cell as described with respect to the other embodiments disclosed herein.

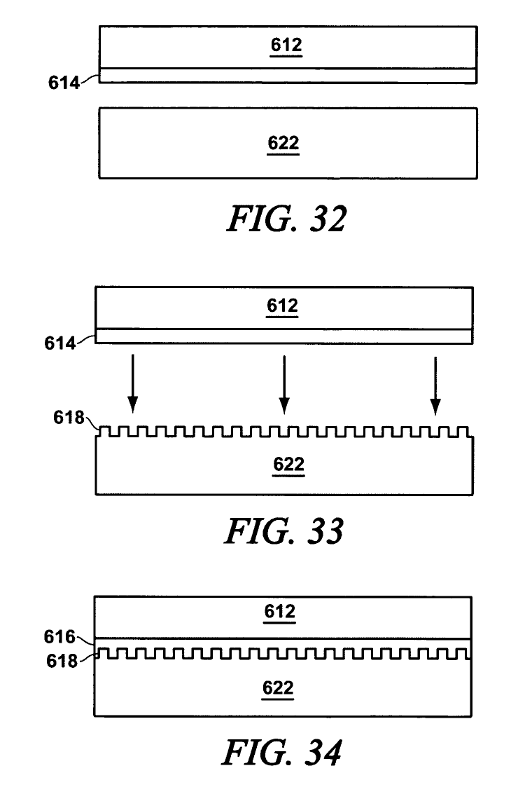

FIGS. 32-34 depict yet another particular, non-limiting embodiment of a process for making a solar cell in accordance with the teachings herein. In accordance with this embodiment, and as shown in FIG. 32, a first substrate 612 and a second substrate 622 are provided. The first substrate 612 may be any of the types described above, and is equipped with a surface metal film 614 which may comprise any of the metals described herein. The second substrate 622 is preferably a semiconductor substrate, and is more preferably a silicon substrate.

With reference to FIG. 33, a textured surface 618 is then imparted to the second substrate 622. This textured surface 618 may be created through a suitable photolithographic process (e.g., by masking and etching), by surface roughening (as, for example, through treatment with a suitable etchant or by mechanical surface abrasion), through the creation of a defect surface and subsequent splitting as described herein, or through the use of other techniques as are known to the art.

Referring now to FIG. 34, the textured surface 618 and the metal film 614 are brought into contact with each other, and the resulting structure is subjected to a suitable heat treatment as described in the previous embodiments to cause the metal film 614 and the textured surface 618 of the second substrate 622 to react and form a silicide layer 616 at the interface.

Various modifications and substitutions may be made to the foregoing embodiments. For example, while frequent reference has been made herein to first substrates and second substrates, it will be appreciated that the methodologies described herein may be applied to various types of substrates, whether or not they constitute wafers. Such substrates include, for example, semiconductor chips, and various types of sheets and surfaces.

Moreover, while the metal silicide layer is preferably patterned by controlling the conditions under which it is formed (e.g., by utilizing conditions which favor the formation of NiSi₂ with facets along the {111} planes), other methods of patterning the metal silicide layer may be used in the devices and methodologies described herein, either in place of, or in combination with, this preferred methodology. For example, the metal silicide layer may be patterned by patterning the metal layer or the surface upon which the metal silicide layer is disposed (see, e.g., the method of FIGS. 32-34), and/or by patterning a surface which the metal silicide layer comes into contact with. Such patterning may be achieved, for example, through suitable photolithographic techniques (e.g., by masking and etching), through surface treatment (e.g., through chemical etching or roughening), or through epitaxy. Such an approach may be especially useful in processes in which the metal silicide does not readily form a texture due, for example, to processing conditions or the chemical composition of the metal silicide.

Moreover, while it is preferred that the metal silicide layer is used as a bonding layer to join two substrates together, it will be appreciated that structures and methodologies in accordance with the teachings herein are possible where this is not the case. For example, in some embodiments, the textured metal silicide layer may be formed in a first structure or substrate, after which the first structure or substrate may be joined to a second structure or substrate. As a specific example of this approach, the first and second structures or substrates may be equipped with first and second oxide layers, respectively, and the first and second structures or substrates may be joined together by joining the first and second oxide layers after the textured metal silicide layer is formed.

The above description of the present invention is illustrative, and is not intended to be limiting. It will thus be appreciated that various additions, substitutions and modifications may be made to the above described embodiments without departing from the scope of the present invention. Accordingly, the scope of the present invention should be construed in reference to the appended claims.

1. A method for forming a photovoltaic device, comprising:
providing a first substrate having a first metal layer disposed thereon;
providing a second substrate which comprises a semiconductor material;
bringing the first metal layer and the second substrate into contact with each other; and
forming a textured metal silicide layer.

2. The method of claim 1, wherein the first metal layer and the second substrate are polished before they are brought into contact with each other.

3. The method of claim 1, wherein forming a texturizing metal-silicide layer comprises annealing the first metal layer and the second substrate.

4. The method of claim 1, wherein the first metal layer and the second substrate are annealed at a temperature within the range of 350° C. to 1200° C.

5. The method of claim 1, wherein the first metal layer comprises nickel, and wherein the second substrate comprises silicon.

6. The method of claim 1, wherein the first metal layer comprises Ni, wherein the second substrate comprises silicon, and wherein forming a textured metal silicide layer occurs under conditions which favor formation of NiSi₂.

7. The method of claim 6, wherein the NiSi₂ forms with facets along {111} planes.

8. The method of claim 1, wherein forming a textured metal silicide layer by texturing the first metal layer or the first or second substrate.

9. The method of claim 1, wherein the second substrate comprises a second metal layer, and wherein the first and second metal layers are brought into contact with each other.

10. A method for forming a photovoltaic device, comprising:
providing a first substrate having a first metal layer disposed thereon;
providing a plurality of structures, wherein each of said structures comprises a semiconductor layer;
bringing the metal layer and the plurality of semiconductor structures into contact with each other; and
interdiffusing the metal layer and the semiconductor layers of the plurality of structures.

11. The method of claim 10, wherein interdiffusing the metal layer and the semiconductor material results in the formation of a metal silicide layer, and further comprising:
texturing the metal-silicide layer.

12. The method of claim 10, wherein the metal layer and the second substrate are polished before bringing the metal layer into contact with the second substrate.

13. The method of claim 10, wherein interdiffusing the metal layer and the second substrate includes annealing the metal layer and the second substrate.

14. The method of claim 10, wherein the plurality of structures comprise first and second structures which are spaced apart from each other, and further comprising:
removing a portion of the metal layer between the first and second structures such that a first portion of the first substrate between the first and second structures is exposed.

15. The method of claim 10, wherein the plurality of structures comprise first and second structures which are spaced apart from each other such that a section of the metal layer is exposed between them, and further comprising:
removing a first portion of the section of the metal layer such that a first portion of the first substrate between the first and second structures is exposed, and such that a second portion of the first substrate between the first and second structures is covered by a second portion of the metal layer.

16. The method of claim 15, further comprising:
depositing a dielectric layer over the first and second structures and the first and second portions of the first substrate; and
subjecting the dielectric layer to an anisotropic etch such that at least some of the second portion of the metal layer is exposed.

17. The method of claim 16, wherein the anisotropic etch results in the formation of spacer structures adjacent to the edges of the first and second structures.

18. The method of claim 16, further comprising:
depositing a first electrically conductive material such that the first electrically conductive material is in contact with the second portion of the metal layer.

19. The method of claim 18, wherein the first electrically conductive material is patterned after deposition to electrically isolate the first and second structures from each other.

20. The method of claim 19, further comprising:
defining grid lines and busbars which extend over the first and second structures.

21-58. (canceled)
